(19) United States
(12) Patent Application Publication
(10) Pub. No.: US 2015/0162516 A1
(43) Pub. Date: Jun. 11, 2015

(54) THERMOELECTRIC MODULE

(71) Applicant: Hyundai Motor Company, Seoul (KR)

(72) Inventors: Man Ju OH, Yongin-si (KR); Jae Woong Kim, Hwaseong-si (KR); Jae Woo Park, Ansan-si (KR)

(73) Assignee: Hyundai Motor Company, Seoul (KR)

(21) Appl. No.: 14/285,054

(22) Filed: May 22, 2014

(30) Foreign Application Priority Data
Dec. 10, 2013 (KR) 10-2013-0152930

(51) Int. Cl. H01L 35/32

(52) U.S. Cl. CPC H01L 35/32

(57) ABSTRACT

A thermoelectric module may include upper and lower panels disposed to be spaced apart from each other in a vertical direction thereof and performing heat conduction, a plurality of semiconductor elements disposed between the upper and lower panels, upper and lower electrodes disposed on inner surfaces of the upper and lower panels facing each other, respectively, and electrically connecting the plurality of semiconductor elements to each other to form a series circuit, and a positive temperature coefficient (PTC) element interposed in the series circuit.

### CROSS REFERENCE TO RELATED APPLICATION

The present application claims priority to Korean Patent Application No. 10-2013-0152930, filed Dec. 10, 2013, the entire contents of which is incorporated herein for all purposes by this reference.

### BACKGROUND OF THE INVENTION

1. Field of the Invention

The present invention relates to a thermoelectric module capable of securing stability by using a positive temperature coefficient (PTC) element so as to perform switching at the time of overheating.

2. Description of Related Art

A thermoelectric module has been used in order to generate power or perform cooling using a Seeback effect or a Peltier effect.

The thermoelectric module has been used to generate power using the Seeback effect, that is, a phenomenon in which electromotive force occurs when a temperature difference is present between both ends or to manufacture a cooling device or a heat generating device using a current through the Peltier effect in which when a current flows to both ends, heat moves along electric charges, such that one side is cooled and another side is heated.

Particularly, the cooling device manufactured using the thermoelectric module has cooling efficiency lower than that of an existing cooling device using a refrigerant, but does not have mechanical noise, may easily control a temperature, and may be environment-friendly. Therefore, the thermoelectric module may be frequently used in a home appliance, a vehicle sheet, or the like, that does not require a very low cooling temperature.

Meanwhile, in the case in which the thermoelectric module has direct current (DC) power supplied thereto, such that one surface thereof is cooled and another surface thereof is heated, a temperature of the heated surface rises to some degree in proportion to a time for which the thermoelectric module is used, such that there is a risk such as a fire, an injury, or the like. Therefore, there is a need to implement a predetermined electrical device (for example, a temperature switch) for controlling this risk.

In addition, since a heat transferring medium is generally disposed on any one surface of an insulating substrate that is heated or cooled and metal electrodes and thermoelectric elements are disposed on another surface thereof, it is difficult to install the predetermined electrical device (for example, the temperature switch) on inner and outer surfaces of the insulating substrates in a region in which two insulating substrates are overlapped with each other. Therefore, the electric device is installed at an outer portion of the region in which the two insulating substrates are overlapped with each other. In this case, a difference is inevitably present between a temperature of the region in which the two insulating substrates are overlapped with each other and a temperature sensed by the electrical device (for example, the temperature switch). Therefore, performance of the electrical device (for example, the temperature switch) may depend on a decrease in this temperature difference.

The matters described as the related art have been provided only for assisting in the understanding for the background of the present invention and should not be considered as corresponding to the related art known to those skilled in the art.

The information disclosed in this Background of the Invention section is only for enhancement of understanding of the general background of the invention and should not be taken as an acknowledgement or any form of suggestion that this information forms the prior art already known to a person skilled in the art.

### BRIEF SUMMARY

Various aspects of the present invention are directed to providing a thermoelectric module capable of securing stability by using a positive temperature coefficient (PTC) element so as to perform switching at the time of overheating.

In an aspect of the present invention, a thermoelectric module may include upper and lower panels disposed to be spaced apart from each other in a vertical direction thereof and performing heat conduction, a plurality of semiconductor elements disposed between the upper and lower panels, upper and lower electrodes disposed on inner surfaces of the upper and lower panels facing each other, respectively, and electrically connecting the plurality of semiconductor elements to each other to form a series circuit, and a positive temperature coefficient (PTC) element interposed in the series circuit.

The thermoelectric module may further include an edge member sealing a space between the upper and lower panels.

Extension electrodes are formed at the upper electrode or the lower electrode and both end portions of the PTC element are connected to the extension electrodes, such that the PTC element is connected in series with the semiconductor elements.

The PTC element is disposed at an outer portion of a space formed by the upper and lower panels.

One end portion of the lower panel is provided with an extension part extended outwardly, the extension part is provided with the PTC element, and the PTC element may have both end portions connected to the series circuit via the extension part, such that the PTC element is connected in series with the semiconductor elements.

The PTC element may have both end portions connected to the series circuit, such that the PTC element is connected in series with the semiconductor elements.

The lower panel may have a heat conduction member attached to a lower surface thereof, and the PTC element is attached to the heat conduction member so as to be thermally connected to the heat conduction member.

The PTC element is disposed, together with the semiconductor elements, at an inner portion of a space formed by the upper and lower panels.

The upper panel may have a heat conduction member attached to an upper surface thereof.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a perspective view of a thermoelectric module according to an exemplary embodiment of the present invention;

FIG. 2 is a cross-sectional view of the thermoelectric module according to an exemplary embodiment of the present invention; and

FIGS. 3 to 5 are views showing various examples of the thermoelectric module according to an exemplary embodiment.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

Hereinafter, exemplary embodiments of the present invention will be described with reference to the accompanying drawings.

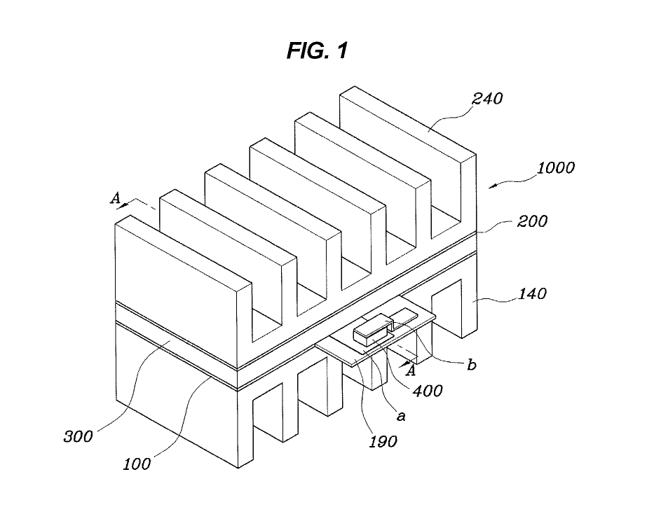

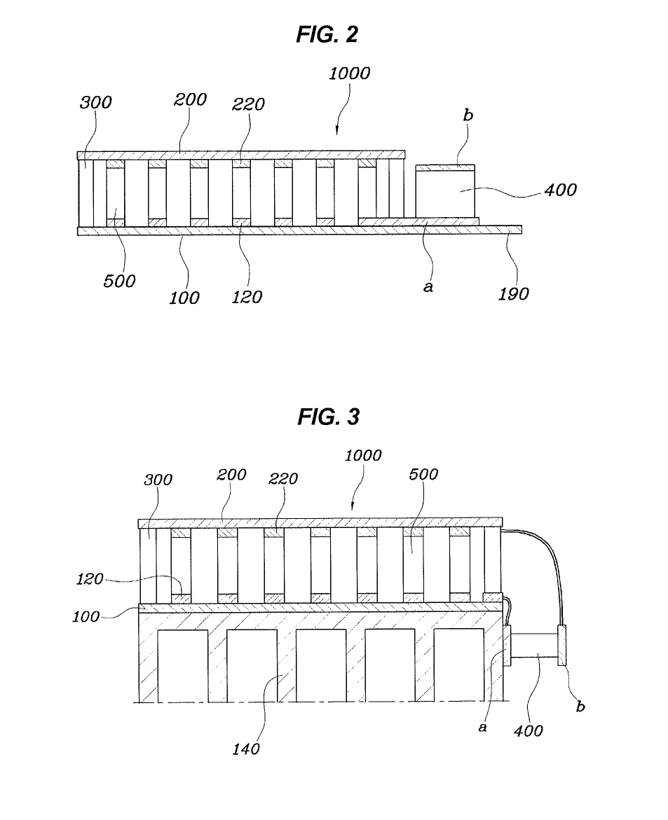

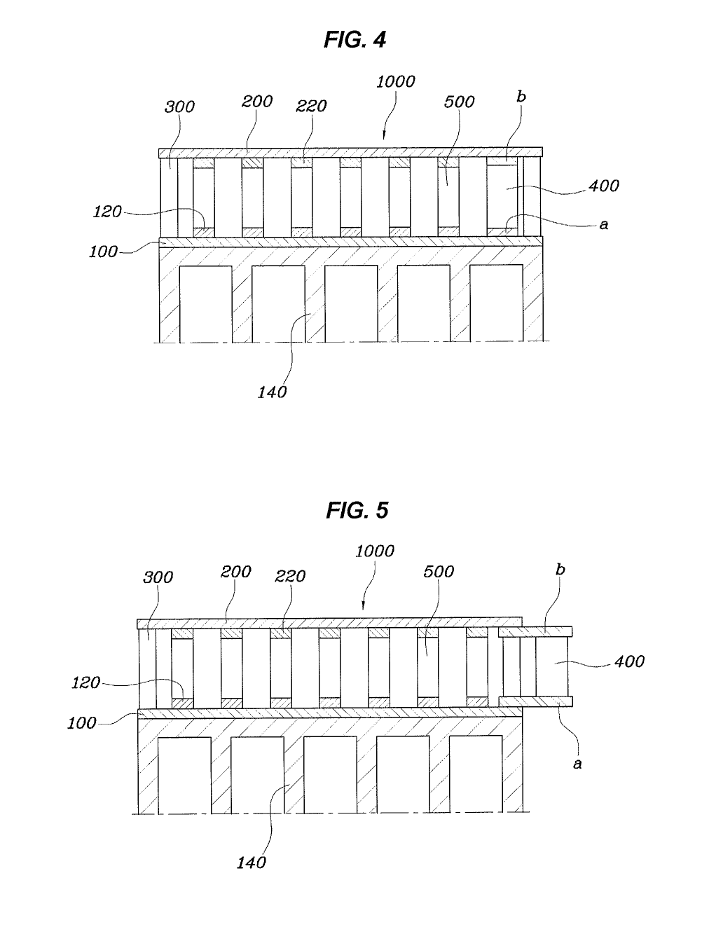

FIG. 1 is a perspective view of a thermoelectric module according to an exemplary embodiment of the present invention, FIG. 2 is a cross-sectional view of the thermoelectric module according to an exemplary embodiment of the present invention, and FIGS. 3 to 5 are views showing various examples of the thermoelectric module according to an exemplary embodiment.

A thermoelectric module according to an exemplary embodiment of the present invention is configured to include upper and lower panels 200 and 100 performing heat conduction and disposed to be spaced apart from each other in a vertical direction, a plurality of semiconductor elements 500 disposed between the upper and lower panels 200 and 100, upper and lower electrodes 220 and 120 disposed on inner surfaces of the upper and lower panels 200 and 100 facing each other, respectively, and electrically connecting the plurality of semiconductor elements 500 to each other to configure a series circuit, and a positive temperature coefficient (PTC) element 400 interposed in the series circuit.

The upper and lower panels 200 and 100 are provided as external covers configuring the thermoelectric module 1000. The upper and lower panels 200 and 100 perform the heat conduction and are disposed to be spaced apart from each other in the vertical direction. In an exemplary embodiment of the present invention shown in the accompanying drawings, the lower panel 100 has a heat conduction member 140 attached to a lower surface thereof and the upper panel 200 has a heat conduction member 240 attached to an upper surface thereof.

The upper and lower panels 200 and 100 may have a predetermined space therebetween, wherein the predetermined space has the plurality of semiconductor elements 500 disposed therein. In addition, the upper and lower electrodes 220 and 120 are disposed on the inner surfaces of the upper and lower panels 200 and 100 facing each other, respectively. The upper and lower electrodes 220 and 120 electrically connect the plurality of semiconductor elements 500 to each other to configure the series circuit. That is, the lower electrodes 120 connect lower ends of the semiconductor elements 500 contacting the lower panel 100 to each other and the upper electrodes 220 connect upper ends of the semiconductor elements 500 contacting the upper panel 200 to allow the plurality of semiconductor elements 500 to be connected to each other as the series circuit.

In addition, the thermoelectric module according to an exemplary embodiment of the present invention may further include an edge member 300 sealing a space between the upper and lower panels 200 and 100.

Meanwhile, the PTC element 400 is interposed in the series circuit to thereby be connected in series with the semiconductor elements 500. In this case, a resistance of the PTC element 400 increases when a temperature rises. In the case in which the resistance of the PTC element 400 increases by a predetermined level, the PTC element 400 is naturally electrically disconnected. Therefore, the series connection circuit configuring the thermoelectric module 1000 is disconnected as an internal resistance increases.

That is, extension electrodes a and b extended in the state in which some of them are disconnected to form both end portions are formed at the upper electrode 220 or the lower electrode 120 and both end portions of the PTC element 400 are connected to both end portions of the extension electrodes a and b, respectively, such that the PTC element 400 may be connected in series with the semiconductor elements 500.

Meanwhile, as shown in FIG. 2, the PTC element 400 may be disposed at an outer portion of the space formed by the upper and lower panels 200 and 100. In this case, one end portion of the lower panel 100 is provided with an extension part 190 extended outwardly, the extension part 190 is provided with the PTC element 400, and the PTC element 400 has both end portions connected to the series circuit, such that the PTC element 400 may be connected in series with the semiconductor elements 500.

In addition, the PTC element 400 may be attached to the heat conduction member 140 attached to the lower panel 100 so as to be thermally connected to the heat conduction member 140, as shown in FIG. 3. In this case, the PTC element 400 performs switching depending on a temperature of the heat conduction member 140.

Meanwhile, as shown in FIG. 4, the PTC element 400 may be disposed, together with the semiconductor elements 500, at an inner portion of the space formed by the upper and lower panels 200 and 100. In this case, the PTC element 400 performs switching depending on an internal temperature.

In addition, as shown in FIG. 5, only electrodes a and b are directly extended outwardly without extension of the lower panel 100, thereby making it possible to allow the PTC element 400 to be connected in series with the semiconductor elements at the outside.

With the thermoelectric element having the structure as described above, the PTC element is used to perform the switching at the time of overheating, thereby making it possible to secure stability.

According to the related art, a structure using an expensive bimetal has been mainly used. However, an exemplary embodiment of the present invention, in which the PTC element is inserted, does not require a separate control, is easily implemented due to a small size and prevents overheating by characteristics of the PTC element itself, such that stability is high and a cost is low.

For convenience in explanation and accurate definition in the appended claims, the terms “upper”, “lower”, “inner” and “outer” are used to describe features of the exemplary embodiments with reference to the positions of such features as displayed in the figures.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A thermoelectric module comprising:
upper and lower panels disposed to be spaced apart from each other in a vertical direction thereof and performing heat conduction;
a plurality of semiconductor elements disposed between the upper and lower panels;
upper and lower electrodes disposed on inner surfaces of the upper and lower panels facing each other, respectively, and electrically connecting the plurality of semiconductor elements to each other to form a series circuit; and
a positive temperature coefficient (PTC) element interposed in the series circuit.

2. The thermoelectric module of claim 1, further comprising an edge member sealing a space between the upper and lower panels.

3. The thermoelectric module of claim 1, wherein extension electrodes are formed at the upper electrode or the lower electrode and both end portions of the PTC element are connected to the extension electrodes, such that the PTC element is connected in series with the semiconductor elements.

4. The thermoelectric module of claim 1, wherein the PTC element is disposed at an outer portion of a space formed by the upper and lower panels.

5. The thermoelectric module of claim 4, wherein one end portion of the lower panel is provided with an extension part extended outwardly, the extension part is provided with the PTC element, and the PTC element has both end portions connected to the series circuit via the extension part, such that the PTC element is connected in series with the semiconductor elements.

6. The thermoelectric module of claim 4, wherein the PTC element has both end portions connected to the series circuit, such that the PTC element is connected in series with the semiconductor elements.

7. The thermoelectric module of claim 4, wherein the lower panel has a heat conduction member attached to a lower surface thereof, and the PTC element is attached to the heat conduction member so as to be thermally connected to the heat conduction member.

8. The thermoelectric module of claim 1, wherein the PTC element is disposed, together with the semiconductor elements, at an inner portion of a space formed by the upper and lower panels.

9. The thermoelectric module of claim 1, wherein the upper panel has a heat conduction member attached to an upper surface thereof.
